(19) United States
(12) Patent Application Publication
(10) Pub. No.: US 2024/0086590 A1
(43) Pub. Date: Mar. 14, 2024

(54) Adaptive Grid Generating Method and Adaptive Grid Generating System

(71) Applicants: Inventec (Pudong) Technology Corp., Shanghai (CN); Inventec Corporation, Taipei (TW)

(72) Inventors: Hsueh-Liang Chen, Taipei (TW); Chen-Chou Huang, Taipei (TW); I-Chang Wang, Taipei (TW); Tzung-Shian Hung, Taipei (TW)

(73) Assignees: Inventec (Pudong) Technology Corp., Shanghai (CN); Inventec Corporation, Taipei (TW)

(21) Appl. No.: 18/208,317

(22) Filed: Jun. 12, 2023

(30) Foreign Application Priority Data
Sep. 13, 2022 (CN) 202211112136.2

(51) Int. Cl. G06F 30/23; G06F 30/17

(52) U.S. Cl. CPC G06F 30/23; G06F 30/17

(57) ABSTRACT

An adaptive grid generating method includes obtaining a first three-dimensional grid of a target structure; importing the first three-dimensional grid into a computer-aided engineering software to obtain a first two-dimensional planar grid; importing the first two-dimensional planar grid into a grid cleaning software to obtain a second two-dimensional planar grid; and importing the second two-dimensional planar grid into the computer-aided engineering software to obtain a second three-dimensional grid.

### BACKGROUND OF THE INVENTION

### 1. Field of the Invention

The present invention relates to an adaptive grid generating method and an adaptive grid generating system, and more particularly, to an adaptive grid generating method and an adaptive grid generating system capable of cleaning and repairing grids.

### 2. Description of the Prior Art

The rapid development of computer systems provides a powerful tool for engineering analysis, so engineers may use numerical simulation methods to simulate the actual problems encountered in the structure of products. For example, when designing the structure of a product, the finite element structure analysis software ABAQUS is used to analyze the grid model of the structure. However, if the structure of the product is very complex, too much information is involved when ABAQUS analyzes the grid model of the structure. Under this circumstance, how to appropriately simplify the structure of the product, and then execute ABAQUS analysis of the grid model to balance efficiency and quality has become a goal of the industry.

### SUMMARY OF THE INVENTION

The present invention is to provide an adaptive grid generating method and an adaptive grid generating system to solve the above problems.

The present invention provides an adaptive grid generating method, including obtaining a first three-dimensional grid of a target structure; importing the first three-dimensional grid into a computer-aided engineering software to obtain a first two-dimensional planar grid; importing the first two-dimensional planar grid into a grid cleaning software to obtain a second two-dimensional planar grid; and importing the second two-dimensional planar grid into the computer-aided engineering software to obtain a second three-dimensional grid.

The present invention provides an adaptive grid generating system, including a processor; and a memory, configured to store a program code for instructing the processor to execute an adaptive grid generating method, and the adaptive grid generating method comprises obtaining a first three-dimensional grid of a target structure; importing the first three-dimensional grid into a computer-aided engineering software to obtain a first two-dimensional planar grid; importing the first two-dimensional planar grid into a grid cleaning software to obtain a second two-dimensional planar grid; and importing the second two-dimensional planar grid into the computer-aided engineering software to obtain a second three-dimensional grid.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an adaptive grid generating system according to an embodiment of the present invention.

FIG. 2 is a flow chart of the adaptive grid generating method according to an embodiment of the present invention.

FIG. 3 is a schematic diagram of the grid model according to an embodiment of the present invention.

FIG. 4 is a schematic diagram of the grid model according to another embodiment of the present invention.

FIG. 5 is a schematic diagram of the second three-dimensional grid according to an embodiment of the present invention.

FIG. 6 is a schematic diagram of the grid cleaning method according to an embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

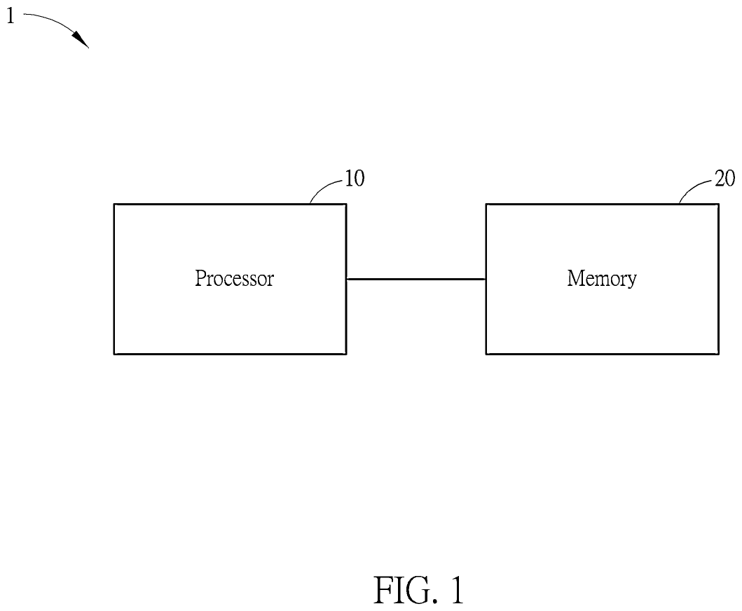

Please refer to FIG. 1. FIG. 1 is a schematic diagram of an adaptive grid generating system 1 according to an embodiment of the present invention. The adaptive grid generating system 1 includes a processor 10 and a memory 20 coupled to each other. The memory 20 is configured to store a program code for instructing the processor 10 to execute an adaptive grid generating method to simplify a grid model of a product structure, in order to quickly analyze the product structure and take into account a quality of the analysis results. It should be noted that the adaptive grid generating system 1 represents the necessary components required to the adaptive grid generating method, and its basic structure is well known in the art, and will not be narrated for brevity. Those skilled in the art may add other components as needed, such as the motherboard, the power supply, the cable, the input devices, etc., but not limited thereto, or may implement the adaptive grid generating system 1 with appropriate devices or equipment.

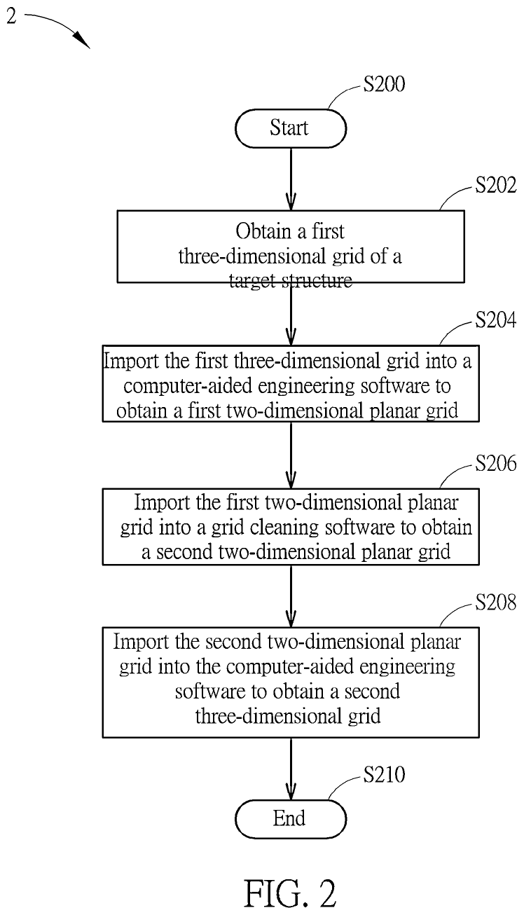

The adaptive grid generating method executed by the adaptive grid generating system 1 may be summarized as a process 2, as shown in FIG. 2. The process 2 includes the following steps:
Step S200: Start.
Step S202: Obtain a first three-dimensional grid of a target structure.
Step S204: Import the first three-dimensional grid into a computer-aided engineering software to obtain a first two-dimensional planar grid.
Step S206: Import the first two-dimensional planar grid into a grid cleaning software to obtain a second two-dimensional planar grid.
Step S208: Import the second two-dimensional planar grid into the computer-aided engineering software to obtain a second three-dimensional grid.
Step S210: End.

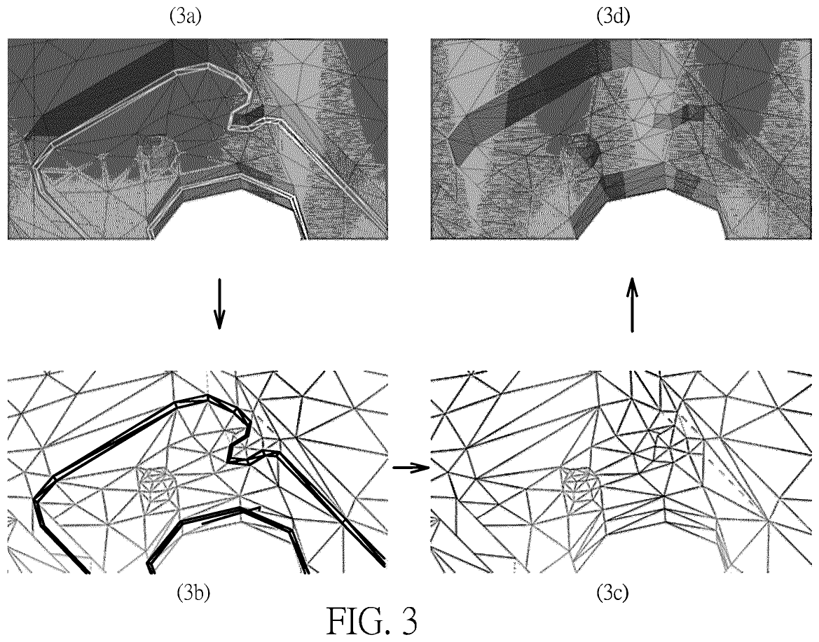

According to the process 2, in step S202, the adaptive grid generating system 1 exports the first three-dimensional grid of the target structure by a drawing software. For example, please refer to FIG. 3, the first three-dimensional grid may be a format file of IDX exported by a software Cero CAD, but not limited thereto. In step S204, the adaptive grid generating system 1 imports the first three-dimensional grid into a computer-aided engineering software to obtain the first two-dimensional planar grid. For example, the computer-aided engineering software may be a finite element structure analysis software ABAQUS. By selecting a 2D Planar mode in ABAQUS, the first three-dimensional grid may be transformed and exported to the first two-dimensional planar grid in an STL format (*.stl), and its basic transformation process is well known in the art, and will not be repeated here.

In step S206, the adaptive grid generating system 1 imports the first two-dimensional planar grid into the grid cleaning software and executes a grid cleaning method to perform grid-clean to the first two-dimensional planar grid, so that the first two-dimensional planar grid may be simplified to the second two-dimensional planar grid. For example, the grid cleaning software may be a Python-based PyMesh suite, which is a rapid prototyping platform for geometry processing and is mainly used in 3D printing. In short, the adaptive grid generating system 1 uses the grid cleaning method in the PyMesh suite to perform grid-clean to the first two-dimensional planar grid and obtain the second two-dimensional planar grid in the STL format.

Specifically, after the above steps, compared with the first two-dimensional planar grid, the second two-dimensional planar grid has removed a part that is suitable to be simplified. Therefore, in step S208, the adaptive grid generating system 1 may import the second two-dimensional planar grid into the computer-aided engineering software ABAQUS to obtain the second three-dimensional grid. In this way, the computer-aided engineering software ABAQUS may analyze the grid model of the target structure according to the second three-dimensional grid and take into account both an analysis efficiency and an analysis quality.

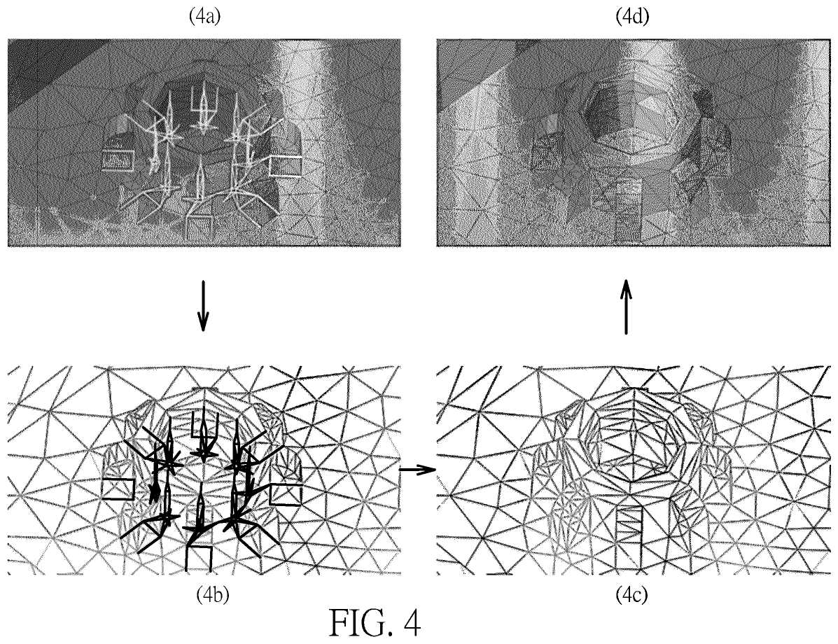

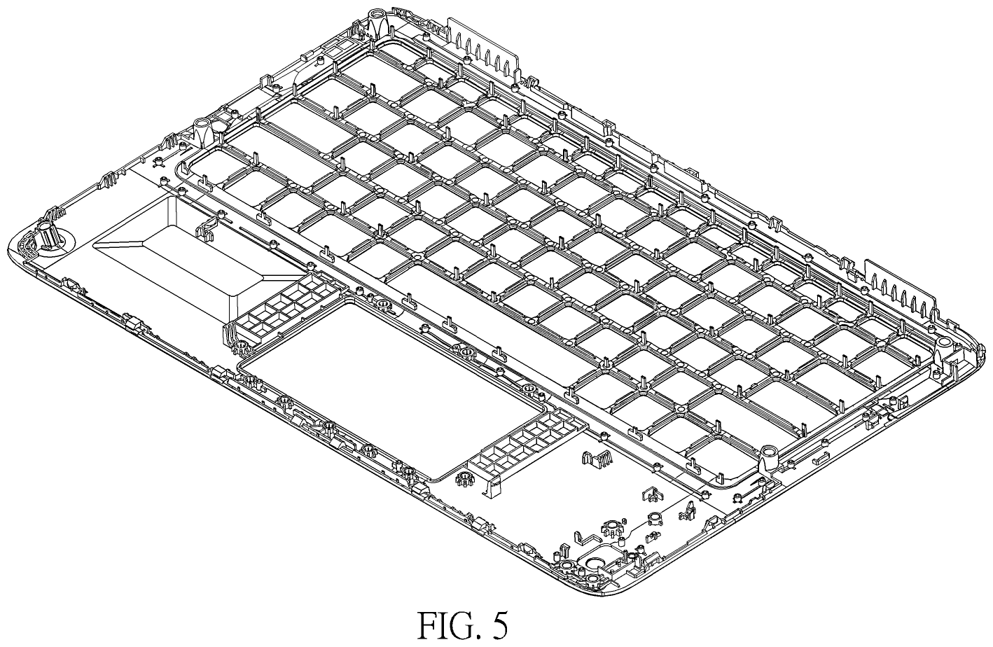

For example, the target structure may be a C component of a notebook. Please refer to FIG. 3, FIG. 4 and FIG. 5. It should be noted that since the structure of the C component is very complex, different parts of the C component are extracted in FIG. 3 and FIG. 4 for illustration. Specifically, FIG. 3a and FIG. 4a are schematic diagrams of the first three-dimensional grids of the C component. The first three-dimensional grid corresponding to the more complex structure of the C component presents a plurality of smaller grids (for example, the plurality of grids are marked with the bold lines). FIG. 3b and FIG. 4b are schematic diagrams of the first two-dimensional planar grid. The adaptive grid generating system 1 transforms the first three-dimensional grid into the first two-dimensional planar grid, where the first two-dimensional planar grid corresponds to the more complex structures of the C component is also marked with the bold lines. FIG. 3c and FIG. 4c are schematic diagrams of the second two-dimensional planar grid. The adaptive grid generating system 1 performs grid-clean to the first two-dimensional planar grid to obtain the second two-dimensional planar grid. As shown in FIG. 3c and FIG. 4c, the regions corresponding to the bold lines in FIG. 3b and FIG. 4b have been cleaned up and simplified. FIG. 3d and FIG. 4d are schematic diagrams of the second three-dimensional grid. The adaptive grid generating system 1 transforms the second two-dimensional planar grid into the second three-dimensional grid. As shown in FIG. 3d and FIG. 4d, compared with the first three-dimensional grid, the second three-dimensional grid has removed parts that are suitable to be simplified. In addition, as shown in FIG. 5, FIG. 5 shows the second three-dimensional grid corresponding to the complete C component, and the computer-aided engineering software ABAQUS may analyze the grid model of the C component according to the second three-dimensional grid and take into account both the analysis efficiency and the analysis quality.

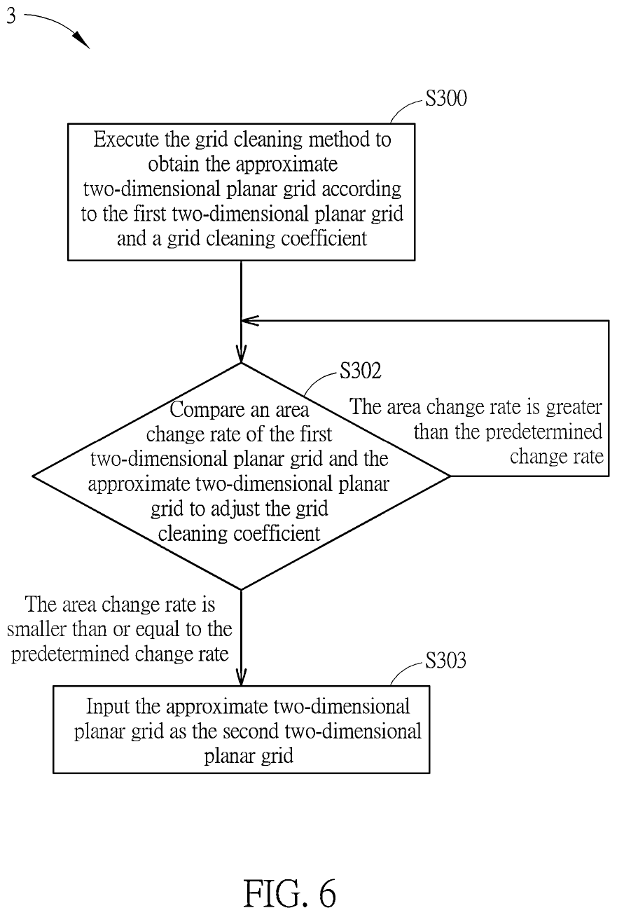

In another embodiment, the grid cleaning method executed by the adaptive grid generating system 1 may be summarized as a process 3, as shown in FIG. 6. The process 3 includes the following steps:
Step S300: Execute the grid cleaning method to obtain the approximate two-dimensional planar grid according to the first two-dimensional planar grid and a grid cleaning coefficient.
Step S302: Compare an area change rate of the first two-dimensional planar grid and the approximate two-dimensional planar grid to adjust the grid cleaning coefficient.
Step S303: Input the approximate two-dimensional planar grid as the second two-dimensional planar grid.

In step S300, the adaptive grid generating system 1 may set the grid cleaning coefficient, and execute the grid cleaning method to the first two-dimensional planar grid according to the grid cleaning coefficient to obtain the approximate two-dimensional planar grid. In step S302, the adaptive grid generating system 1 compares the area change rate of the first two-dimensional planar grid and the approximate two-dimensional planar grid. When the area change rate of the first two-dimensional planar grid and the approximate two-dimensional planar grid is greater than a predetermined change rate, the adaptive grid generating system 1 adjusts the grid cleaning coefficient of the grid cleaning method, and executes the process 3 again. When the area change rate of the first two-dimensional planar grid and the approximate two-dimensional planar grid is smaller than the predetermined change rate, the adaptive grid generating system 1 inputs the approximate two-dimensional planar grid as the second two-dimensional planar grid. For example, the adaptive grid generating system 1 sets the predetermined change rate to 3%. When the area change rate is greater than 3%, the adaptive grid generating system 1 adjusts the grid cleaning coefficient, and executes the process 3 again. When the area change rate is smaller than 3%, the adaptive grid generating system 1 inputs the approximate two-dimensional planar grid as the second two-dimensional planar grid.

It should be noted that the adaptive grid generating system 1 is an embodiment of the present invention. Those skilled in the art should readily make combinations, modifications and/or alterations on the abovementioned description and examples. The abovementioned description, steps, procedures and/or processes including suggested steps can be realized by means that could be hardware, software, firmware (known as a combination of a hardware device and computer instructions and data that reside as read-only software on the hardware device), an electronic system, or combination thereof. Examples of hardware can include analog, digital and mixed circuits known as microcircuit, microchip, or silicon chip. Examples of the electronic system may include a system on chip (SoC), system in package (SiP), a computer on module (CoM) and the electronic system. Any of the abovementioned procedures and examples above may be compiled into program codes or instructions that are stored in the memory 20. The memory 20 may include read-only memory (ROM), flash memory, random access memory (RAM), subscriber identity module (SIM), hard disk, floppy diskette, or CD-ROM/DVD-ROM/BD-ROM, but not limited thereto. The processor 10 may read and execute the program codes or the instructions stored in the memory 20 for realizing the abovementioned functions.

In summary, compared to the prior art, the adaptive grid generating system of the present invention may use the grid cleaning software to clean the grid model of the target structure, and then import into the computer-aided engineering software to analyze the target structure, so as to reduce a large amount of calculations of the analysis software and take into account the accuracy of the analysis.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An adaptive grid generating method, comprising:
(a) obtaining a first three-dimensional grid of a target structure;
(b) importing the first three-dimensional grid into a computer-aided engineering software to obtain a first two-dimensional planar grid;
(c) importing the first two-dimensional planar grid into a grid cleaning software to obtain a second two-dimensional planar grid; and
(d) importing the second two-dimensional planar grid into the computer-aided engineering software to obtain a second three-dimensional grid.

2. The adaptive grid generating method of claim 1, wherein the computer-aided engineering software is ABAQUS.

3. The adaptive grid generating method of claim 1, wherein the step (c) comprises:
performing a grid cleaning method to obtain an approximate two-dimensional planar grid according to the first two-dimensional planar grid;
when the first two-dimensional planar grid and the approximate two-dimensional planar grid have an area change rate greater than a predetermined change rate, adjusting a grid cleaning coefficient of the grid cleaning method, and performing the step (c) again; and
when the first two-dimensional planar grid and the approximate two-dimensional planar grid have the area change rate smaller than or equal to the predetermined change rate, inputting the approximate two-dimensional planar grid as the second two-dimensional planar grid.

4. The adaptive grid generating method of claim 3, wherein the grid cleaning software is PyMesh.

5. An adaptive grid generating system, comprising:
a processor; and
a memory, configured to store a program code for instructing the processor to execute an adaptive grid generating method, and the adaptive grid generating method comprises:
(a) obtaining a first three-dimensional grid of a target structure;
(b) importing the first three-dimensional grid into a computer-aided engineering software to obtain a first two-dimensional planar grid;
(c) importing the first two-dimensional planar grid into a grid cleaning software to obtain a second two-dimensional planar grid; and
(d) importing the second two-dimensional planar grid into the computer-aided engineering software to obtain a second three-dimensional grid.

6. The adaptive grid generating system of claim 5, wherein the computer-aided engineering software is ABAQUS.

7. The adaptive grid generating system of claim 5, wherein the step (c) comprises:
performing a grid cleaning method to obtain an approximate two-dimensional planar grid according to the first two-dimensional planar grid;
when the first two-dimensional planar grid and the approximate two-dimensional planar grid have an area change rate greater than a predetermined change rate, adjusting a grid cleaning coefficient of the grid cleaning method, and performing the step (c) again; and
when the first two-dimensional planar grid and the approximate two-dimensional planar grid have the area change rate smaller than or equal to the predetermined change rate, inputting the approximate two-dimensional planar grid as the second two-dimensional planar grid.

8. The adaptive grid generating system of claim 7, wherein the grid cleaning software is PyMesh.
